(19) United States
(12) Patent Application Publication
(10) Pub. No.: US 2025/0346811 A1
(43) Pub. Date: Nov. 13, 2025

(54) PROCESSING SOLUTION, PROCESSING METHOD OF SEMICONDUCTOR SUBSTRATE, AND MANUFACTURING METHOD OF SEMICONDUCTOR DEVICE

(71) Applicant: TOKYO OHKA KOGYO CO., LTD., Kanagawa (JP)

(72) Inventor: Eita SUGA, Kanagawa (JP)

(21) Appl. No.: 19/182,797

(22) Filed: Apr. 18, 2025

(30) Foreign Application Priority Data
May 8, 2024 (JP) 2024-075697

(51) Int. Cl. C09K 13/08; C23F 1/26; H01L 21/311; H01L 21/3213

(52) U.S. Cl. CPC C09K 13/08; C23F 1/26; H01L 21/31111; H01L 21/32134

(57) ABSTRACT

There are provided a processing solution including an oxidizing agent, a fluorine-based compound, an alkali metal compound and/or an alkaline earth metal compound, and water; a processing method of a semiconductor substrate using the same; and a manufacturing method of a semiconductor device using the same.

### CROSS-REFERENCE TO RELATED APPLICATIONS

The present application claims priority to Japan patent application No. 2024-075697, filed with the Japan Patent Office on May 8, 2024, the entire content of which is incorporated herein by reference.

### BACKGROUND OF THE INVENTION

### Technical Field

The present invention relates to a processing solution, a processing method of a semiconductor substrate, and a manufacturing method of a semiconductor device.

### Description of the Related Art

In manufacturing a semiconductor element such as IC or LSI or a liquid crystal panel element, first, an insulating film such as a conductive metal film, a SiO₂ film, or a tantalum nitride film is formed by CVD deposition on a substrate such as a silicon wafer or glass. Next, photoresist is uniformly applied onto the conductive metal film or the insulating film and is selectively exposed and developed to form a photoresist pattern. Then, using the pattern as a mask, the conductive metal film or the insulating film is selectively etched to form a fine circuit, and then an unnecessary photoresist layer is removed by a stripping solution, thereby manufacturing a semiconductor element or a liquid crystal panel element.

As a technique related to such etching, for example, Patent Literature 1 discloses an etchant for a silicon semiconductor member, the etchant including hydrofluoric acid and iodic acid or an iodate compound represented by Mₘ(IOₙ)ₚ (M represents hydrogen, any of 1 to 3 valent metal, or NH₄, m represents 1, 2, 3, or 5, n represents 3, 4, or 6, and p represents 1, 2, or 3). Patent Literature 2 discloses a chemical solution used for removing a transition metal-containing material on a substrate, the chemical solution containing one or more periodic acids selected from the group consisting of periodic acid and salts thereof and a compound containing one or more anions selected from the group consisting of IO₃⁻, I⁻, and I₃⁻, in which a content of the compound containing anion is 5 ppb by mass to 1% by mass with respect to a total mass of the chemical solution. Patent Literature 3 discloses an etching solution composition for performing an etching process on a MoSi film, the etching solution composition containing less than 3.5% by weight of a fluorine compound, water, and an iodine-containing oxidizing agent.
Patent Literature 1: JP2681433B
Patent Literature 2: JP2023-078285A
Patent Literature 3: JP2018-174212A

### SUMMARY OF THE INVENTION

However, in recent years, miniaturization of wiring in a semiconductor substrate is further progressed, and development of a processing solution having a high etching processing speed is required for etching of metal containing a tantalum atom. However, there is still room for improvement in this respect.

The present invention is conceived in view of such circumstances, and an object of the present invention is to provide a processing solution having an excellent etching processing speed of metal containing a tantalum atom, a processing method of a semiconductor substrate using the processing solution, and a manufacturing method of a semiconductor device.

As a result of intensive studies to achieve the above-described object, the present inventor found use of a processing solution including an oxidizing agent, a fluorine-based compound, an alkali metal compound and/or an alkaline earth metal compound, and water, thereby completing the present invention. That is, the present invention is as follows.

(1)

A processing solution including an oxidizing agent, a fluorine-based compound, an alkali metal compound and/or an alkaline earth metal compound, and water.

(2)

The processing solution according to (1), wherein the oxidizing agent is an iodine-containing oxidizing agent.

(3)

The processing solution according to (1), wherein the oxidizing agent is iodic acid.

(4)

The processing solution according to any one of (1) to (3), wherein the fluorine-based compound is at least one selected from the group consisting of hydrogen fluoride, ammonium fluoride, hexafluorosilicic acid, ammonium hydrogen fluoride, hexafluoroboric acid, and tetramethylammonium fluoride.

(5)

The processing solution according to any one of (1) to (3), wherein a pH is less than 4.0.

(6)

The processing solution according to any one of (1) to (4), wherein a content of the fluorine-based compound is 2.5 mmol/L or more and 2500 mmol/L or less.

(7)

The processing solution according to any one of (1) to (6), wherein the processing solution is used for etching a layer containing Ta or TaN.

(8)

A processing method including a step of removing a layer containing Ta or TaN from a semiconductor substrate including the layer containing Ta or TaN by bringing the semiconductor substrate into contact with the processing solution according to any one of (1) to (7).

(9)

An article formed by the processing method according to (8), wherein the article is a semiconductor device.

(10)

The article according to (9), wherein the semiconductor device is a transistor.

(11)

A manufacturing method of a semiconductor device, the manufacturing method including a step of removing a layer containing Ta or TaN from a semiconductor substrate including the layer containing Ta or TaN by by bringing the semiconductor substrate into contact with the processing solution according to any one of (1) to (7).

(12)

The manufacturing method according to (11), wherein the semiconductor device is an integrated circuit.

According to the present invention, it is possible to provide a processing solution having an excellent etching processing speed of metal containing a tantalum atom, a processing method of a semiconductor substrate using the processing solution, and a manufacturing method of a semiconductor device.

### DETAILED DESCRIPTION OF THE INVENTION

Hereinafter, modes for carrying out the present invention (hereinafter, simply referred to as “the present embodiment”) are described in detail. The following embodiments are examples for describing the present invention and are not intended to limit the present invention to the following contents. The present invention can be appropriately modified and implemented within the scope of the gist thereof.

In numerical ranges described in stages in the present disclosure, an upper limit value or a lower limit value described in one numerical range may be replaced with an upper limit value or a lower limit value of another numerical range described in stages. In a numerical range described in the present disclosure, an upper limit value or a lower limit value of the numerical range may be replaced with a value described in the examples.

### <Processing Solution>

The processing solution according to the present embodiment contains an oxidizing agent, a fluorine-based compound, an alkali metal compound and/or an alkaline earth metal compound, and water. According to the processing solution according to the present embodiment, metal or a metal layer containing at least a tantalum atom can be etched at a high etching processing speed. The reason is not clear, but for example, the following reason may be considered.

When metal or a metal layer containing a tantalum atom is processed using the processing solution including a fluorine-based compound, an oxidizing agent, and water, tantalum is considered to be dissolved in water by a two-stage reaction. For example, when hydrogen fluoride is used as the fluorine-based compound, it is considered that tantalum is oxidized by the oxidizing agent to become tantalum oxide (Ta₂O₃) in reaction of the first stage (first reaction). Subsequently, it is considered that tantalum oxide reacts with a fluorine ion to become a tantalum fluoride ion (TaF₆⁻) and the tantalum fluoride ion is dissolved in water in reaction of the second stage (second reaction).

The processing solution according to the present embodiment contains an alkali metal compound and/or an alkaline earth metal compound in addition to the fluorine-based compound and the oxidizing agent. In an example using hydrogen fluoride as the fluorine-based compound, tantalum as the metal, and potassium hydroxide (KOH) as the alkali metal and/or alkaline earth metal, it is considered that tantalum forms a potassium salt of tantalum oxide (KTaO₃) in the first reaction. In the second reaction, it is considered that the potassium salt of tantalum oxide (KTaO₃) reacts with fluorine ions to form a potassium salt of tantalum fluoride (KTaF₆). As described above, the processing solution according to the present embodiment contains at least a fluorine-based compound, an oxidizing agent, an alkali metal compound and/or an alkaline earth metal compound, and water, so that the first reaction and the second reaction described above can be promoted. As a result, it is presumed that a metal or a metal layer containing a tantalum atom can be etched at a high etching processing speed (however, the mechanism and the effect of the present embodiment are not limited thereto).

Hereinafter, components, physical properties, and the like that can be blended in the processing solution (also referred to as “cleaning solution”, “etching solution”, or the like) according to the present embodiment are described.

### (Oxidizing Agent)

The processing solution according to the present embodiment contains an oxidizing agent. The oxidizing agent preferably does not correspond to a fluorine-based compound described below. Examples of the oxidizing agent may include halogen oxyacid, permanganic acid, and salts thereof, and hydrogen peroxide, ozone, and cerium (IV) salts. Here, examples of the halogen oxyacid may include an iodine-containing oxidizing agent, a bromine-containing oxidizing agent, and a chlorine-containing oxidizing agent. Specific examples thereof may include hypochlorous acid, chlorous acid, chloric acid, perchloric acid, hypobromous acid, bromous acid, bromic acid, perbromic acid, hypoiodous acid, iodous acid, iodic acid, metaperiodic acid, and orthoperiodic acid. Among these, preferable is an iodine-containing oxidizing agent, more preferable is hypoiodous acid, iodous acid, iodic acid, metaperiodic acid, or orthoperiodic acid, and further more preferable is iodic acid.

The oxidizing agent may be used alone or in combination of two or more kinds thereof.

The content of the oxidizing agent in the processing solution according to the present embodiment is preferably 0.1 mmol/L or more and 6000 mmol/L or less. The lower limit value thereof is more preferably 0.5 mmol/L or more, further more preferably 1.0 mmol/L or more, and still more preferably 2.0 mmol/L or more. The upper limit value thereof is more preferably 2900 mmol/L or less, further more preferably 2000 mmol/L or less, still more preferably 100 mmol/L or less, and even still more preferably 50 mmol/L or less. When the content of the oxidizing agent is the above-described lower limit value or more, it can be expected that the surface of the metal or the metal layer containing the tantalum atom is effectively oxidized. When the content is the upper limit value or less described above, it can be expected that excessive oxidation of noble metal is effectively prevented. Note that when two or more kinds of oxidizing agents are used in combination, the total content thereof is preferably within the above numerical range.

### (Fluorine-Based Compound)

The processing solution according to the present embodiment contains a fluorine-based compound. The fluorine-based compound is a compound containing a fluorine atom. The fluorine-based compound is preferably a compound not including a metal ion. Specific examples of the fluorine-based compound may include ammonium fluoride (AF), hydrogen fluoride (HF), hexafluorosilicic acid, hexafluoroboric acid, ammonium hydrogen fluoride, tetramethylammonium fluoride, ammonium borofluoride, methylamine hydrogen fluoride, ethylamine hydrogen fluoride, propylamine hydrogen fluoride, tetramethylammonium fluoride, tetraethylammonium fluoride, ethanolamine hydrogen fluoride, methylethanolamine hydrogen fluoride, dimethylethanolamine hydrogen fluoride, hydroxylamine hydrogen fluoride, dimethylhydroxylamine hydrogen fluoride, and triethylenediamine hydrogen fluoride.

Among these compounds, from the viewpoint of a dissolution speed of metal oxide oxidized by the oxidizing agent, preferable is at least one selected from the group consisting of hydrogen fluoride, ammonium fluoride, hexafluorosilicic acid, hexafluoroboric acid, ammonium hydrogen fluoride, and tetramethylammonium fluoride is preferable, and more preferable is hydrogen fluoride. It is also preferable to use two or more selected from the group consisting of hydrogen fluoride, ammonium fluoride, hexafluorosilicic acid, hexafluoroboric acid, ammonium hydrogen fluoride, and tetramethylammonium fluoride in combination.

The content of the fluorine-based compound in the processing solution according to the present embodiment is preferably 2.5 mmol/L or more and 2500 mmol/L or less. The lower limit value thereof is more preferably 25 mmol/L or more, further more preferably 250 mmol/L or more, still more preferably 400 mmol/L or more, and even still more preferably 700 mmol/L or more. The upper limit value thereof is more preferably 2000 mmol/L or less and further more preferably 1500 mmol/L or less. When the content of the fluorine-based compound is the above-mentioned lower limit value or more, the metal oxide can be effectively dissolved by fluoride ions. When the content is the above-described upper limit value or less, it is possible to impart more excellent selectivity to a wiring material such as Cu. Note that when two or more fluorine-based compounds are used in combination, the total content thereof is preferably within the above numerical range.

### (Alkali Metal Compound and Alkaline Earth Metal Compound)

The processing solution according to the present embodiment contains an alkali metal compound and/or an alkaline earth metal compound. Note that the alkali metal compound and the alkaline earth metal compound are compounds other than the oxidizing agent and the fluorine-based compound described above.

The alkali metal compound is not particularly limited as long as the alkali metal compound contains alkali metal, and examples thereof may include a carbonate of alkali metal, a carboxylate of alkali metal, a hydrogen salt of alkali metal, a sulfate of alkali metal, a phosphate of alkali metal, a borate of alkali metal, an organic acid salt of alkali metal, an oxide of alkali metal, a hydroxide of alkali metal, and a chloride of alkali metal.

Specific examples of the alkali metal may include sodium, potassium, and cesium. Specific examples of the alkali metal compound may include sodium hydrogen carbonate, sodium hydroxide, potassium hydroxide, cesium hydroxide, potassium carbonate, potassium iodide, and sodium chloride.

The alkaline earth metal compound is not particularly limited as long as the alkaline earth metal compound contains alkaline earth metal, and examples thereof may include a carbonate of alkaline earth metal, a carboxylate of alkaline earth metal, a hydrogen salt of alkaline earth metal, a sulfate of alkaline earth metal, a phosphate of alkaline earth metal, a borate of alkaline earth metal, an organic acid hydrochloride of alkaline earth metal, an oxide of alkaline earth metal, a hydroxide of alkaline earth metal, and a chloride of alkaline earth metal. Specific examples of the alkaline earth metal may include barium and calcium.

Specific examples of the alkaline earth metal compound may include barium hydroxide, calcium hydroxide, and calcium chloride.

The alkali metal compound and/or the alkaline earth metal compound may be used alone or in combination of two or more kinds thereof.

The content of the alkali metal compound and/or the alkaline earth metal compound in the processing solution according to the present embodiment is preferably 0.15 mmol/L or more and 200 mmol/L or less. The lower limit value thereof is more preferably 0.8 mmol/L or more, further preferably 1.5 mmol/L or more, still more preferably 2 mmol/L or more, and even more preferably 3 mmol/L or more. The upper limit value thereof is more preferably 100 mmol/L or less, further more preferably 50 mmol/L or less, still more preferably 10 mmol/L or less, and even still more preferably 4 mmol/L or less. When the content of the alkali metal compound and/or the alkaline earth metal compound is the above-described lower limit value or more, it is preferable from the viewpoint of solubility, and when the content is the above-described upper limit value or less, it is preferable from the viewpoint of the metal residue after rinsing. Note that when two or more kinds of alkali metal compounds and/or alkaline earth metal compounds are used in combination, the total content thereof is preferably within the above numerical range.

### (Water)

The processing solution according to the present embodiment contains water as a solvent. The water used in the processing solution according to the present embodiment is preferably water subjected to a purification process such as distilled water, ion-exchanged water, and ultrapure water and more preferably ultrapure water generally used for semiconductor manufacturing.

The content of water in the processing solution according to the present embodiment is not particularly limited but is preferably 0.56 mol/L or more and 55 mol/L or less. The lower limit value thereof is more preferably 2.8 mol/L or more and further more preferably 5.6 mol/L or more. The upper limit value thereof is more preferably 54 mol/L or less and further more preferably 53 mol/L or less. When the content of water is the above-mentioned lower limit value or more, it can be expected that temporal stability is maintained. When the content is the above-mentioned upper limit value or less, excellent metal solubility can be expected.

### (pH of Processing Solution)

The pH of the processing solution according to the present embodiment is not particularly limited but is preferably less than 4.0, more preferably less than 3.5, further more preferably less than 3.0, and still more preferably less than 2.5. The pH of the processing solution is preferably 0.5 or more, more preferably 1.0 or more, further more preferably 1.5 or more, and still more preferably 2.0 or more. As one aspect of the combination of the upper limit value and the lower limit value of the pH of the processing solution, the pH is preferably 0.5 or more and less than 4.0, more preferably 1.0 or more and less than 3.5, further more preferably 1.5 or more and less than 3.0, and still more preferably 2.0 or more and less than 2.5. When the pH of the processing solution is the above-described upper limit value or less, it can be expected that solubility of metal containing a tantalum atom (such as tantalum (Ta), tantalum nitride (TaN), and tantalum oxide (TaOₓ)) is further improved. When the pH of the processing solution is the above-described lower limit value or more, it can be expected that selectivity during etching of the metal containing a tantalum atom with respect to a wiring material such as Cu is further improved. For example, when including a tantalum layer and/or a tantalum nitride layer and metal containing Cu (such as Cu, Cu alloy, and AlCu), it can be expected that residues resulting from tantalum and/or tantalum nitride are efficiently removed with high selectivity.

### (pH Adjusting Agent)

The processing solution according to the present embodiment may contain a pH adjusting agent as long as the purpose of the present embodiment is not missed. The pH adjusting agent is preferably at least one selected from the group consisting of acid and salts thereof. Specific examples of the pH adjusting agent may include methanesulfonic acid, trifluoromethanesulfonic acid, oxalic acid dihydrate, citric acid, tartaric acid, picolinic acid, succinic acid, acetic acid, lactic acid, sulfosuccinic acid, benzoic acid, propionic acid, formic acid, pyruvic acid, maleic acid, malonic acid, fumaric acid, malic acid, ascorbic acid, mandelic acid, heptanoic acid, butyric acid, valeric acid, glutaric acid, phthalic acid, hypophosphorous acid, salicylic acid, 5-sulfosalicylic acid, hydrochloric acid, ethanesulfonic acid, butanesulfonic acid, p-toluenesulfonic acid, dichloroacetic acid, difluoroacetic acid, monochloroacetic acid, monofluoroacetic acid, trichloroacetic acid, trifluoroacetic acid, hydrobromic acid (62% by mass), sulfuric acid, ammonium acetate, potassium acetate, tetramethylammonium acetate and other tetraalkylammonium acetates, phosphonium acetate, ammonium butyrate, ammonium trifluoroacetate, ammonium carbonate, ammonium chloride, ammonium sulfate, phosphoric acid, diammonium hydrogen phosphate, ammonium dihydrogen phosphate, bis(tetramethylammonium) hydrogen phosphate, ditetraalkylammonium hydrogen phosphate, ditetraalkylammonium dihydrogen phosphate, diphosphonium hydrogen phosphate, phosphonium dihydrogen phosphate, ammonium phosphonate, tetraalkylammonium phosphonate, phosphonium phosphonate, etidronic acid, and salts thereof.

The processing solution according to the present embodiment may contain a basic compound as the pH adjusting agent. Examples of the basic compound may include organic alkaline compounds and inorganic alkaline compounds. Examples of the inorganic alkaline compound may include ammonium hydroxide, and examples of the organic alkaline compound may include quaternary ammonium salts including organic quaternary ammonium hydroxides, and salts of alkylamines and derivatives thereof such as trimethylamine and triethylamine.

The pH adjusting agent may be used alone or in combination of two or more kinds thereof.

### (Surfactant)

The processing solution according to the present embodiment may contain a surfactant for adjusting wettability of the processing solution to an object to be processed. Examples of the surfactant may include a nonionic surfactant, an anionic surfactant, a cationic surfactant, and an amphoteric surfactant.

Examples of the nonionic surfactant may include a polyalkylene oxide alkyl phenyl ether-based surfactant, a polyalkylene oxide alkyl ether-based surfactant, a block polymer-based surfactant including polyethylene oxide and polypropylene oxide, a polyoxyalkylene distyrenated phenyl ether-based surfactant, a polyalkylene tribenzyl phenyl ether-based surfactant, and an acetylene polyalkylene oxide-based surfactant.

Examples of the anionic surfactant may include alkyl sulfonic acid, alkyl benzene sulfonic acid, alkyl naphthalene sulfonic acid, alkyl diphenyl ether sulfonic acid, fatty acid amide sulfonic acid, polyoxyethylene alkyl ether carboxylic acid, polyoxyethylene alkyl ether acetic acid, polyoxyethylene alkyl ether propionic acid, alkyl phosphonic acid, and salts of fatty acid. Examples of the salts may include ammonium salt, sodium salt, potassium salt, and tetramethylammonium salt.

Examples of the cationic surfactant may include a quaternary ammonium salt-based surfactant and an alkylpyridine-based surfactant.

Examples of the amphoteric surfactant may include a betaine-based surfactant, an amino acid-based surfactant, an imidazoline-based surfactant, and an amine oxide-based surfactant.

The surfactant may be used alone or in combination of two or more kinds thereof.

### (Water-Soluble Organic Solvent)

The processing solution according to the present embodiment may contain a water-soluble organic solvent. A water-soluble organic solvent miscible with other components contained in the processing solution according to the present embodiment can be suitably used. In the present embodiment, a suitable kind and content of the water-soluble organic solvent can be appropriately selected considering the kind and the content of other components in the processing solution.

Specific examples of the water-soluble organic solvent may include sulfoxides such as dimethyl sulfoxide (DMSO); sulfones such as dimethylsulfone, diethylsulfone, bis(2-hydroxyethyl) sulfone, and tetramethylene sulfone; amides such as N,N-dimethylformamide (DMF), N-methylformamide, N,N-dimethylacetamide, N-methylacetamide, and N,N-diethylacetamide; lactams such as N-methyl-2-pyrrolidone (NMP), N-ethyl-2-pyrrolidone, N-propyl-2-pyrrolidone, N-hydroxymethyl-2-pyrrolidone, and N-hydroxyethyl-2-pyrrolidone; imidazolidinones such as 1,3-dimethyl-2-imidazolidinone, 1,3-diethyl-2-imidazolidinone, and 1,3-diisopropyl-2-imidazolidinone; lactones such as γ-butyrolactone and 8-valerolactone; and polyhydric alcohols and derivatives thereof such as ethylene glycol, ethylene glycol monomethyl ether, ethylene glycol monoethyl ether, ethylene glycol monobutyl ether, ethylene glycol monomethyl ether acetate, ethylene glycol monoethyl ether acetate, diethylene glycol, diethylene glycol monomethyl ether, diethylene glycol monoethyl ether, and diethylene glycol monobutyl ether.

Note that the processing solution according to the present embodiment may be a so-called aqueous processing solution or an organic solvent-based processing solution, and is preferably an aqueous processing solution from the viewpoint of the degree of effect desired as the processing solution such as an etching effect or a cleaning effect, economic efficiency, load on the environment, and the like. The aqueous processing solution refers to a processing solution containing only water as a solvent and a processing solution in which the content of water is larger than the content of the organic solvent. The organic solvent-based processing solution refers to a processing solution in which the content of water is smaller than the content of the organic solvent. Examples of the organic solvent may include the above-described water-soluble organic solvent. In the processing solution according to the present embodiment, the mass ratio of the water content to the total of the water content and the organic solvent content (water/(water+organic solvent)) is not particularly limited, and is preferably 0.5 or more, preferably 0.8 or more, more preferably 0.9 or more, and further more preferably 1 (containing only water as a solvent).

### (Other Components)

The processing solution according to the present embodiment may contain other additives used in the semiconductor processing solution in the related arts as long as the object of the present embodiment is not impaired. Examples of other components may include a metal anticorrosive, a reducing agent, a complexing agent, a chelating agent, an antifoaming agent, and a stabilizer. The additives may be used alone or in combination of two or more kinds thereof.

As described above, since the processing solution according to the present embodiment is excellent in at least the etching processing speed of metal containing a tantalum atom, the processing solution according to the present embodiment can be suitably used as a processing solution used for etching a layer containing tantalum (Ta) or tantalum nitride (TaN). That is, the processing solution according to the present embodiment can be suitably used when etching a layer containing tantalum (Ta) (tantalum layer) and/or a layer containing tantalum nitride (TaN) (tantalum nitride layer). Note that examples of tantalum and tantalum-based alloy contained in the metal and the metal layer containing a tantalum atom may include tantalum (Ta), tantalum nitride (TaN), and tantalum oxide (TaOₓ) (the examples may be collectively referred to as “tantalum and tantalum-based alloy”).

As an aspect of the processing solution according to the present embodiment, it is possible to reduce the etching processing speed for copper while enhancing the etching processing speed for metal containing a tantalum atom. That is, it is also possible to selectively etch the metal containing a tantalum atom while damage to copper is prevented. That is, it is also possible to selectively etch the metal containing a tantalum atom with respect to copper. As a specific example, when the processing solution according to the present embodiment is used to process a substrate in which a metal layer containing a tantalum atom (Ta layer) and copper (Cu) simultaneously exist, processing can be performed so that a selection ratio (Ta/Cu) of the Ta layer etching processing speed to the Cu etching processing speed is high. As another specific example, when the processing solution according to the present embodiment is used to process a substrate in which a metal layer containing tantalum nitride (TaN layer) and copper simultaneously exist, processing can be performed so that a selection ratio (TaN/Cu) of the TaN layer etching processing speed to the Cu etching processing speed is high.

The selection ratio (Ta/Cu) of the etching processing speed of the metal layer containing a tantalum atom (Ta layer) to the etching processing speed of copper that can be achieved by the processing solution according to the present embodiment is preferably 0.5 or more, more preferably 0.8 or more, and further more preferably 1.1 or more.

The selection ratio (TaN/Cu) of the etching processing speed of the metal layer containing tantalum nitride (TaN layer) to the etching processing speed of copper that can be achieved by the processing solution according to the present embodiment is preferably 1.4 or more, more preferably 2.2 or more, and further more preferably 3.0 or more.

As described above, the processing solution according to the present embodiment can be suitably used for etching metal containing a tantalum atom (tantalum and tantalum-based alloy) such as tantalum and/or tantalum nitride.

### (Impurity and the Like)

The processing solution according to the present embodiment may contain, for example, a metal impurity including metal atoms such as a Fe atom, a Cr atom, a Ni atom, a Zn atom, a Ca atom, and a Pb atom. The total content of the metal atoms in the processing solution of the present embodiment is preferably 100 ppt by mass or less with respect to the total mass of the processing solution. The lower limit value of the total content of the metal atoms is preferably as low as possible, and is, for example, 0.001 ppt by mass or more. The total content of the metal atoms is, for example, 0.001 ppt by mass to 100 ppt by mass. By setting the total content of the metal atoms to the above-described preferable upper limit value or less, defect suppressing property and residue suppressing property of the cleaning liquid are improved. It is considered that when the total content of the metal atoms is set to the above-described preferable lower limit value or more, the metal atoms hardly exist in the system separately, and the manufacturing yield of the entire object to be cleaned is hardly adversely affected.

The content of the metal impurity can be adjusted, for example, by a purification process such as filtering. The purification process such as filtering may be performed on a part of or the entire raw material before preparing the cleaning liquid or may be performed after the processing solution is prepared.

The processing solution of the present embodiment may contain, for example, an impurity derived from an organic substance (organic impurity). The total content of the organic impurity in the processing solution of the present embodiment is preferably 5000 ppm by mass or less. The lower limit value of the total content of the organic impurity is preferably as low as possible, and is, for example, 1 ppq by mass or more. The total content of the organic impurity may, for example, be from 1 ppq by mass to 5000 ppm by mass.

The processing solution according to the present embodiment may contain, for example, an object to be counted having a size countable by a light scattering type in-liquid particle counter. The size of the object to be counted is, for example, 0.04 μm or more. The number of the object to be counted in the processing solution according to the present embodiment per 1 mL of the processing solution is, for example, 1000 or less, and the lower limit value thereof is, for example, 1 or more. It is considered that, when the number of the object to be counted in the processing solution is within the above-described range, the effect of preventing metal corrosion, the effect of reducing defects, and the like by the processing solution are improved (however, the mechanism and the effect of the present embodiment are not limited thereto).

The size of the object to be counted may be a size detectable by a light scattering type in-liquid particle counter and may be, for example, 0.001 μm or more.

The organic impurity and/or the object to be counted described above may be added to the cleaning liquid or may be inevitably mixed into the cleaning liquid in a manufacturing process of the processing solution. Examples of cases where the organic impurity is inevitably mixed in the manufacturing process of the processing solution may include a case where the organic impurity is included in a raw material (for example, an organic solvent) used for manufacturing the processing solution, and a case where the organic impurity is mixed from an external environment in the manufacturing process of the processing solution (for example, contamination), and the present embodiment is not limited thereto.

When the object to be counted is added to the processing solution, an abundance ratio may be adjusted for each specific size considering surface roughness and the like of the object to be cleaned.

### <Processing Method>

As described above, the processing solution according to the present embodiment can be suitably used for processing a metal layer of metal containing a tantalum atom (tantalum and tantalum-based alloy). Among the methods, a preferred example of the processing method according to the present embodiment is a processing method including a step of bringing a semiconductor substrate including a layer containing Ta or TaN into contact with the above-described processing solution and removing the layer containing Ta or TaN. Here, it is needless to say that the semiconductor substrate may be a semiconductor substrate on which both the Ta layer and the TaN layer are mounted.

The semiconductor substrate to be processed is not particularly limited, and examples thereof may include various substrates such as a semiconductor wafer, a glass substrate for photomask, a glass substrate for liquid crystal display, a glass substrate for plasma display, a substrate for field emission display (FED), a substrate for optical disk, a substrate for magnetic disk, and a substrate for magneto-optical disk. As the semiconductor substrate to be processed, a substrate used for manufacturing a semiconductor device is preferable. Preferable examples of the semiconductor device may include a transistor. For example, a thermal oxide film (TEOS), a boron phosphorus glass film (BPSG), and the like are formed on the substrate. The substrate may include various layers and structures (for example, metal wiring, a gate structure, a source structure, a drain structure, an insulating layer, a ferromagnetic layer, or a nonmagnetic layer) as appropriate. Size, thickness, shape, layer structure, and the like of the substrate are not particularly limited and can be appropriately selected according to the purpose.

The step of bringing the semiconductor processing solution into contact with the semiconductor substrate may be performed as a step of etching the semiconductor substrate using the above-described processing solution or may be performed as a step of removing residues on the semiconductor substrate by bringing the above-described processing solution into contact with the surface of the semiconductor substrate after dry etching. It is needless to say that contents described as a manufacturing method described below may also be appropriately carried out as the processing method within a range not departing from the purpose of the present embodiment.

The method of the etching process is not particularly limited, and known etching methods and etching conditions can be used. Specific examples thereof may include a spraying method, an immersion method, and a liquid pouring method, but the present embodiment is not limited thereto. In the spray method, for example, the semiconductor substrate is conveyed or rotated in a predetermined direction, and the above-described processing solution is sprayed, jetted, or applied to the space, so that the above-described processing solution can be brought into contact with the semiconductor substrate. If necessary, the above-described processing solution may be sprayed, jetted, or applied while the substrate is rotated with a spin coater. In the immersion method, the semiconductor substrate can be immersed in the above-described processing solution, so that the processing solution can be brought into contact with the semiconductor substrate. In the liquid pouring method, the above-described processing solution is poured onto the semiconductor substrate, so that the semiconductor substrate and the processing solution can be brought into contact with each other.

The etching processing methods can be appropriately selected according to structure, material, and the like of the semiconductor substrate. When using the spray method or the liquid pouring method, the supply amount of the semiconductor processing solution to the semiconductor substrate may be any amount as long as the surface to be processed in the semiconductor substrate is sufficiently wetted with the processing solution described above. The purpose of the etching process is not particularly limited, and may be fine processing of a surface to be processed containing a material to be processed of the semiconductor substrate, may be removal of an adhering substance adhered to the semiconductor substrate, or may be cleaning of a surface to be processed including a coating film of the semiconductor substrate.

In the processing method according to the present embodiment, as a processing temperature when using the processing solution described above, a suitable temperature can be appropriately selected according to the purpose of use or the like. From the viewpoint of the etching processing speed of metal containing a tantalum atom and selectivity to copper, the processing temperature is preferably, for example, from 15° C. to 60° C. The upper limit value thereof is more preferably 50° C. or lower, further more preferably 45° C. or lower, and still more preferably 40° C. or lower. The lower limit value thereof is more preferably 20° C. or higher and further more preferably 25° C. or higher. In any of the spray method, the immersion method, and the liquid pouring method, by setting the temperature to the above range, it is possible to maintain a high etching processing speed of metal or the like containing a tantalum atom, and it is also expected to prevent an unintended composition change of the processing solution.

The time for performing the etching process may be appropriately selected according to the purpose of the etching process, the amount of the material to be processed and to be removed by etching (for example, the thickness of the layer containing the material to be processed, the amount of the attached substance containing the material to be processed, and the like), and the etching processing conditions.

### (Other Steps)

The processing method of a substrate according to the present embodiment may include other steps in addition to the step of bringing the semiconductor processing solution into contact with the semiconductor substrate. The other steps are not particularly limited, and examples thereof may include known steps performed when a semiconductor element is manufactured. Examples of such steps may include channel formation, High-K/metal gate formation, a formation step of each structure such as metal wiring, a gate structure, a source structure, a drain structure, an insulating layer, a ferromagnetic layer, and a nonmagnetic layer (layer formation, etching other than the above etching process, chemical mechanical polishing, transformation, and the like), a resist film formation step, an exposure step, a development step, a heat processing step, a cleaning step, and an inspection step, but the present embodiment is not limited thereto. The other steps can be appropriately performed before or after the etching processing step as necessary.

After the processing method according to the present embodiment is performed, a step of cleaning and/or rinsing the semiconductor substrate may be performed as necessary. For example, the semiconductor substrate (or the semiconductor device) can be cleaned and/or rinsed using at least one selected from the group consisting of water, methanol, isopropanol, ethylene glycol, a surfactant, and a mixture thereof. After cleaning or rinsing, the semiconductor substrate can be dried by nitrogen gas, spin dry cycle, steam drying, or the like.

As such, preferable examples of the article formed by the processing method according to the present embodiment may include a semiconductor device and a transistor.

### <Manufacturing Method of Semiconductor Device>

The processing method according to the present embodiment can be suitably used in a manufacturing method of a semiconductor device. Preferable examples of the semiconductor device in the present embodiment may include a manufacturing method of a semiconductor device including a step of removing a layer containing tantalum (Ta) or tantalum nitride (TaN) from a semiconductor substrate including the layer containing tantalum (Ta) or tantalum nitride (TaN) by bringing the semiconductor substrate into contact with the above-described processing solution. As a method and conditions of the step, the contents described in the above-described processing method can be appropriately adopted.

One of more specific preferable examples of the manufacturing method of the semiconductor device according to the present embodiment may include a manufacturing method of a semiconductor device including:
(i) a step of forming a resist pattern on a substrate including a metal layer containing copper (Cu);
(ii) a step of dry-etching a substrate using the resist pattern as a mask; and
(iii) a step of removing a residue material from the substrate using a processing solution containing an oxidizing agent, a fluorine-based compound, an alkali metal compound and/or an alkaline earth metal compound, and water.

The ashing step may be performed as necessary after the step (ii) (dry-etching step). That is, the step (ii) may be a step of performing (ii-1) a step of dry-etching the substrate using the resist pattern as a mask and (ii-2) a step of ashing the resist pattern. In the manufacturing method (or the processing method) according to the present embodiment, after the etching process and the ashing process are performed on the substrate using the resist pattern (photoresist pattern or the like) provided on the substrate as a mask, the substrate can be processed using the processing solution described above.

The step (i) is described. For example, a photoresist layer is formed on a substrate such as a silicon wafer or glass. An insulating film such as a conductive metal film/metal oxide film, a SiO₂ film, a tantalum film, or a tantalum nitride film may be formed on the substrate by vapor deposition or the like as desired. Examples of the metal such as the conductive metal film and the metal oxide film may include aluminum (Al); aluminum alloy (Al alloy) such as aluminum-silicon (Al—Si); copper (Cu); copper alloy (Cu alloy) such as copper-silicon (Cu—Si); aluminum-copper alloy (AlCu alloy) such as aluminum-copper (Al—Cu) and aluminum-silicon-copper (Al—Si—Cu); titanium (Ti); titanium alloy (Ti alloy) such as titanium nitride (TiN) and titanium tungsten (TiW); tantalum (Ta), tantalum nitride (TaN), tungsten (W), and tungsten nitride (WN). The layers may be formed on the substrate as a single layer or may be formed on the substrate as a plurality of layers.

The step (ii) is described. As the resist, for example, a photoresist pattern is formed on the substrate. Here, the exposure condition and the development condition can be appropriately selected according to the purpose and the photoresist to be used. During exposure, for example, the photoresist layer can be exposed through a desired mask pattern by a light source (for example, a low-pressure mercury lamp, a high-pressure mercury lamp, an ultra-high-pressure mercury lamp, and a xenon lamp) that emits an active ray such as an ultraviolet ray, a far ultraviolet ray, an excimer laser, an X-ray, or an electron beam. Alternatively, the photoresist layer may be irradiated with a scanning electron beam. Thereafter, a post-exposure heat process (post exposure baking) may be performed as necessary.

Then, pattern development is performed using a developer for photoresist, and a predetermined photoresist pattern can be obtained. Note that the developing method is not particularly limited, and a known method can be adopted. For example, it is possible to adopt an appropriate development method according to the purpose, such as immersion development in which a substrate coated with a photoresist is immersed in a developer for a certain period of time, and then washed with water and dried; paddle development in which a developer is dropped on the surface coated with the photoresist, is allowed to stand for a certain period of time, and then washed with water and dried; and spray development in which a developer is sprayed onto the photoresist surface, and then washed with water and dried.

Subsequently, using the formed photoresist pattern as a mask, the conductive metal film/metal oxide film or the insulating film is selectively etched by dry etching or the like to form a fine circuit. Thereafter, an unnecessary photoresist layer is removed by plasma ashing as necessary.

The step (iii) is described. When etching, or etching and ashing are performed in the step (ii), resist residues and metal deposition generated during metal film etching adhere to and remain as residue materials on the substrate surface. The residue materials are immersed or brought into contact with the processing solution according to the present embodiment to remove residue materials adhered to and remaining on the substrate. By using the processing solution according to the present embodiment, the residue materials are easily removed. In particular, when a metal layer containing a tantalum atom and a metal member or a metal layer containing a copper atom are provided, residues resulting from tantalum can be removed with high selectivity. More specifically, when including a tantalum layer and/or a tantalum nitride layer and metal containing Cu (such as Cu, Cu alloy, and AlCu), residues resulting from tantalum and/or tantalum nitride can be removed with high selectivity.

As the processing conditions using the processing solution according to the present embodiment, suitable conditions can be selected considering configuration, material, and characteristics of the desired semiconductor device, conditions of etching and ashing, and the like. For example, the processing temperature and the processing time described in the processing method can be used.

After the processing using the processing solution according to the present embodiment, a step of cleaning and/or rinsing the substrate may be performed as necessary. In the step, the method and the conditions of the cleaning step and the rinsing step described in the above-described processing method can be adopted.

Since the processing solution according to the present embodiment can be suitably used as the aqueous processing solution as described above, in addition to the above-described various effects, an effect that the processing solution is efficiently distilled off from the processed semiconductor substrate (semiconductor device) in the subsequent cleaning step or rinsing step can be expected. The processing solution according to the present embodiment can also be used as an aspect not containing metal ions (metal-free processing solution).

In the present embodiment, the semiconductor device can be suitably manufactured by the above-described manufacturing method. Preferable examples of the semiconductor device obtained as such may include an integrated circuit.

### Examples

The present invention is described in more detail with reference to the following examples and comparative examples, but the present invention is not limited to the following examples at all.

### <Preparation of Processing Solution>

The processing solutions of the respective examples and the respective comparative examples were prepared to have the compositions described in the respective tables described below. As the components used, those classified as semiconductor grade or those classified as high purity grade equivalent thereto were used unless otherwise specified.

Note that the abbreviations of the components used are as follows.
HIO₃: Iodic acid
HF: Hydrogen fluoride
KOH: Potassium hydroxide
KI: Potassium iodide
NaOH: Sodium hydroxide
NaCl: Sodium chloride
CsOH: Cesium hydroxide
CaCl₂): Calcium chloride
H₂SO₄: Sulfuric acid
NH₄OH: Ammonium hydroxide
DIW: Ultrapure water

### <Evaluation of Etching Rate>

First, a Ta layer, a TaN layer, and a Cu layer were respectively formed on silicon substrates by a PVD method to obtain test substrates of 2 cm×2 cm (test substrate of Ta layer, test substrate of TaN layer, and test substrate of Cu layer).

Then, the test substrates were placed in a 200 ml beaker filled with 100 mL of the processing solution of each example and each comparative example, and the etching process was performed at the temperatures shown in the respective tables for 10 minutes while stirring at 300 rpm.

The etching rates of Ta, TaN, and Cu were respectively obtained by dividing the differences in film thickness before and after etching of the respective metal layers of the used test substrate by the etching time. Note that the film thicknesses were measured with a scanning X-ray fluorescence spectrometer (manufactured by Rigaku Holdings Corporation, model number ZSX Primus IV) under vacuum conditions using a fundamental parameter method (FP method).

### 1. Experiment 1

### Examples 1 to 7 and Comparative Examples 1 and 2

Table 1 shows compositions, processing conditions, evaluation results, and the like of the processing solutions of the respective examples and the respective comparative examples. Note that, when the column of the content of the component in Table 1 is blank, the blank column indicates that the corresponding component is not contained. For example, when using the processing solution of Comparative Example 1, the processing solution contains 22.7 mmol/L of HIO₃ and 999.7 mmol/L of HF, does not contain KOH, KI, NaOH, NaCl, CsOH, and CaCl₂), contains water as the remainder, and has a pH of 2.4. “-” in the unit column in Table 1 indicates that there is no unit, and “-” in the columns of the examples indicates that there is no measurement result or no calculation result.

TABLE 1

| | | Comparative | | Comparative | | | | | | |
|---|---|---|---|---|---|---|---|---|---|---|
| | Unit | Example 1 | Example 1 | Example 2 | Example 2 | Example 3 | Example 4 | Example 5 | Example 6 | Example 7 |
| HlO₃ | mmol/L | 22.7 | 22.7 | 22.7 | 22.7 | 22.7 | 22.7 | 22.7 | 22.7 | 22.7 |
| HF | mmol/L | 999.7 | 999.7 | 999.7 | 999.7 | 999.7 | 999.7 | 999.7 | 999.7 | 999.7 |
| KOH | mmol/L | | 3.56 | | 3.56 | | | | | |
| Kl | mmol/L | | | | | 3.56 | | | | |
| NaOH | mmol/L | | | | | | 3.56 | | | |
| NaCl | mmol/L | | | | | | | 3.56 | | |
| CsOH | mmol/L | | | | | | | | 3.56 | |
| CaCl₂ | mmol/L | | | | | | | | | 3.56 |
| DlW | — | Remainder | Remainder | Remainder | Remainder | Remainder | Remainder | Remainder | Remainder | Remainder |
| Processing solution volume | mL | 100 | 100 | 100 | 100 | 100 | 100 | 100 | 100 | 100 |
| Processing solution pH | — | 2.4 | 2.4 | 2.4 | 2.4 | 2.4 | 2.4 | 2.4 | 2.4 | 2.4 |
| Processing temperature | ° C. | 25 | 25 | 35 | 35 | 35 | 35 | 35 | 35 | 35 |
| Etching rate of | nm/min | 9.52 | 20.60 | 13.15 | 26.05 | 24.08 | 16.28 | 18.09 | 15.48 | 15.24 |
| TaN layer (A) | | | | | | | | | | |
| Etching rate of | nm/min | 2.04 | 5.13 | 4.25 | 9.66 | 8.66 | 7.40 | 7.28 | 4.90 | 4.93 |
| Ta layer (B) | | | | | | | | | | |
| Etching rate of | nm/min | 8.35 | 5.87 | 12.1 | 8.47 | — | — | — | — | — |
| Cu layer (C) | | | | | | | | | | |
| Etching rate of | — | 1.14 | 3.51 | 1.09 | 3.08 | — | — | — | — | — |
| TaN layer/Etching | | | | | | | | | | |
| rate of Cu layer | | | | | | | | | | |
| (A/C) | | | | | | | | | | |
| Etching rate of | — | 0.24 | 0.87 | 0.35 | 1.14 | — | — | — | — | — |
| Ta layer/Etching | | | | | | | | | | |
| rate of Cu layer | | | | | | | | | | |
| (B/C) | | | | | | | | | | |

### 2. Experiment 2

### Examples 2 and 8 to 12 and Comparative Examples 2 to 5

Table 2 shows compositions, processing conditions, evaluation results, and the like of the processing solutions of the respective examples and the respective comparative examples. Note that, when the column of the content of the component in Table 2 is blank, the blank column indicates that the corresponding component is not contained. In Table 2, sulfuric acid or ammonium hydroxide was added as necessary so that the pH is adjusted to a desired pH. “-” in the unit column in Table 2 indicates that there is no unit, and “-” in the column of Comparative Example 5 indicates that there is no calculation result.

TABLE 2

| | | Comparative | Comparative | Comparative | Comparative | |
|---|---|---|---|---|---|---|
| | Unit | Example 3 | Example 2 | Example 4 | Example 5 | Example 8 |
| HlO₃ | mmol/L | 22.7 | 22.7 | 22.7 | 22.7 | 22.7 |
| HF | mmol/L | 999.7 | 999.7 | 999.7 | 999.7 | 999.7 |
| KOH | mmol/L | | | | | 3.56 |
| NH₄OH | mmol/L | | | 52.14 | 237.16 | |
| H₂SO₄ | mmol/L | 50.98 | | | | 50.98 |
| DlW | — | Remainder | Remainder | Remainder | Remainder | Remainder |
| Processing solution volume | mL | 100 | 100 | 100 | 100 | 100 |
| Processing solution pH | — | 2.1 | 2.4 | 2.5 | 3.4 | 2.1 |
| Processing temperature | ° C. | 35 | 35 | 35 | 35 | 35 |
| Etching rate of TaN layer | nm/min | 17.80 | 13.15 | 9.80 | <1 | 28.60 |
| (A) | | | | | | |
| Etching rate of Ta layer | nm/min | 4.54 | 4.25 | 1.68 | <1 | 10.60 |
| (B) | | | | | | |
| Etching rate of Cu layer | nm/min | 18.34 | 12.1 | 6.94 | <1 | 12.6 |
| (C) | | | | | | |
| Etching rate of TaN layer/ | — | 0.97 | 1.09 | 1.41 | — | 2.27 |
| Etching rate of Cu layer | | | | | | |
| (A/C) | | | | | | |
| Etching rate of Ta layer/ | — | 0.25 | 0.35 | 0.24 | — | 0.84 |
| Etching rate of Cu layer | | | | | | |
| (B/C) | | | | | | |

| | Unit | Example 2 | Example 9 | Example 10 | Example 11 | Example 12 |
|---|---|---|---|---|---|---|
| HlO₃ | mmol/L | 22.7 | 22.7 | 22.7 | 22.7 | 22.7 |
| HF | mmol/L | 999.7 | 999.7 | 999.7 | 999.7 | 999.7 |
| KOH | mmol/L | 3.56 | 3.56 | 3.56 | 3.56 | 3.56 |
| NH₄OH | mmol/L | | 17.12 | 34.25 | 51.37 | 120.83 |
| H₂SO₄ | mmol/L | | | | | |
| DlW | — | Remainder | Remainder | Remainder | Remainder | Remainder |
| Processing solution volume | mL | 100 | 100 | 100 | 100 | 100 |
| Processing solution pH | — | 2.4 | 2.5 | 2.6 | 3 | 3.5 |
| Processing temperature | ° C. | 35 | 35 | 35 | 35 | 35 |
| Etching rate of TaN layer | nm/min | 26.05 | 17.60 | 16.40 | 15.50 | 12.90 |
| (A) | | | | | | |
| Etching rate of Ta layer | nm/min | 9.66 | 6.50 | 6.10 | 5.70 | 4.80 |
| (B) | | | | | | |
| Etching rate of Cu layer | nm/min | 8.47 | 5.32 | 5.83 | 4.5 | 3.3 |
| (C) | | | | | | |
| Etching rate of TaN layer/ | — | 3.08 | 3.31 | 2.81 | 3.44 | 3.91 |
| Etching rate of Cu layer | | | | | | |
| (A/C) | | | | | | |
| Etching rate of Ta layer/ | — | 1.14 | 1.22 | 1.05 | 1.27 | 1.45 |
| Etching rate of Cu layer | | | | | | |
| (B/C) | | | | | | |

### 3. Experiment 3

### Examples 2 and 13 to 19, and Comparative Examples 2, 6, and 7

Table 3 shows compositions, processing conditions, evaluation results, and the like of the processing solutions of the respective examples and the respective comparative examples. Note that, when the column of the content of the component in Table 3 is blank, the blank column indicates that the corresponding component is not contained. “-” in the unit column in Table 3 indicates that there is no unit, and “-” in the columns of the comparative examples and the examples indicates that there is no measurement result or no calculation result.

TABLE 3

| | | Comparative | Comparative | Comparative | | | |
|---|---|---|---|---|---|---|---|
| | Unit | Example 6 | Example 7 | Example 2 | Example 13 | Example 14 | Example 2 |
| HlO₃ | mmol/L | 22.7 | 22.7 | 22.7 | 22.7 | 22.7 | 22.7 |
| HF | mmol/L | 499.9 | 749.8 | 999.7 | 499.9 | 749.8 | 999.7 |
| KOH | mmol/L | | | | 3.56 | 3.56 | 3.56 |
| DlW | — | Remainder | Remainder | Remainder | Remainder | Remainder | Remainder |
| Processing solution volume | mL | 100 | 100 | 100 | 100 | 100 | 100 |
| Processing solution pH | — | 2.4 | 2.4 | 2.4 | 2.4 | 2.4 | 2.4 |
| Processing temperature | ° C. | 35 | 35 | 35 | 35 | 35 | 35 |
| Etching rate of TaN layer (A) | nm/min | <1 | 4.43 | 13.15 | 5.32 | 8.16 | 26.05 |
| Etching rate of Ta layer (B) | nm/min | <1 | 1.54 | 4.25 | 1.98 | 5.64 | 9.66 |
| Etching rate of Cu layer (C) | nm/min | 2.36 | 4.99 | 12.1 | 3.48 | 5.54 | 8.47 |
| Etching rate of TaN layer/ | — | — | 0.89 | 1.09 | 1.53 | 1.47 | 3.08 |
| Etching rate of Cu layer | | | | | | | |
| (A/C) | | | | | | | |
| Etching rate of Ta layer/ | — | — | 0.31 | 0.35 | 0.57 | 1.02 | 1.14 |
| Etching rate of Cu layer | | | | | | | |
| (B/C) | | | | | | | |

| | Unit | Example 15 | Example 16 | Example 17 | Example 18 | Example 19 |
|---|---|---|---|---|---|---|
| HlO₃ | mmol/L | 22.7 | 2.8 | 11.4 | 22.7 | 22.7 |
| HF | mmol/L | 1249.6 | 999.7 | 999.7 | 999.7 | 999.7 |
| KOH | mmol/L | 3.56 | 3.56 | 3.56 | 1.78 | 2.67 |
| DlW | — | Remainder | Remainder | Remainder | Remainder | Remainder |
| Processing solution volume | mL | 100 | 100 | 100 | 100 | 100 |
| Processing solution pH | — | 2.4 | 2.5 | 2.4 | 2.4 | 2.4 |
| Processing temperature | ° C. | 35 | 35 | 35 | 35 | 35 |
| Etching rate of TaN layer (A) | nm/min | 37.52 | 23.55 | 25.77 | 20.27 | 26.33 |
| Etching rate of Ta layer (B) | nm/min | 14.52 | 8.73 | 9.55 | 7.52 | 9.76 |
| Etching rate of Cu layer (C) | nm/min | 11.59 | — | — | — | — |
| Etching rate of TaN layer/ | — | 3.24 | — | — | — | — |
| Etching rate of Cu layer | | | | | | |
| (A/C) | | | | | | |
| Etching rate of Ta layer/ | — | 1.25 | — | — | — | — |
| Etching rate of Cu layer | | | | | | |
| (B/C) | | | | | | |

From the above, it was at least confirmed that the processing solutions of the present examples are excellent in the etching processing speed of metal containing a tantalum atom.

What is claimed is:

1. A processing solution comprising:
an oxidizing agent;
a fluorine-based compound;
an alkali metal compound and/or an alkaline earth metal compound; and
water.

2. The processing solution according to claim 1, wherein
the oxidizing agent is an iodine-containing oxidizing agent.

3. The processing solution according to claim 1, wherein
the oxidizing agent is iodic acid.

4. The processing solution according to claim 1, wherein
the fluorine-based compound is at least one selected from the group consisting of hydrogen fluoride, ammonium fluoride, hexafluorosilicic acid, ammonium hydrogen fluoride, hexafluoroboric acid, and tetramethylammonium fluoride.

5. The processing solution according to claim 1, wherein
a pH is less than 4.0.

6. The processing solution according to claim 4, wherein
a content of the fluorine-based compound is 2.5 mmol/L or more and 2500 mmol/L or less.

7. The processing solution according to claim 1, wherein
the processing solution is used for etching a layer containing Ta or TaN.

8. A processing method comprising: a step of removing a layer containing Ta or TaN from a semiconductor substrate including the layer containing Ta or TaN by bringing the semiconductor substrate into contact with the processing solution according to claim 1.

9. An article formed by the processing method according to claim 8, wherein the article is a semiconductor device.

10. The article according to claim 9, wherein the semiconductor device is a transistor.

11. A manufacturing method of a semiconductor device, the manufacturing method comprising: a step of removing a layer containing Ta or TaN from a semiconductor substrate including the layer containing Ta or TaN by bringing the semiconductor substrate into contact with the processing solution according to claim 1.

12. The manufacturing method according to claim 11, wherein the semiconductor device is an integrated circuit.
